(19) United States
(12) Patent Application Publication
(10) Pub. No.: US 2025/0239979 A1
(43) Pub. Date: Jul. 24, 2025

(54) METHOD AND CIRCUIT FOR MEASURING A CURRENT

(71) Applicant: STMicroelectronics International N.V., Geneva (CH)

(72) Inventor: Nicolas Aupetit, Saint Jean de Moirans (FR)

(21) Appl. No.: 19/032,366

(22) Filed: Jan. 20, 2025

(30) Foreign Application Priority Data
Jan. 23, 2024 (FR) FR2400635

(51) Int. Cl. H03G 7/06; G01R 19/00; G06G 7/24; H03F 3/45

(52) U.S. Cl. CPC H03G 7/06; G01R 19/0092; G06G 7/24; H03F 3/45273; H03F 2200/129

(57) ABSTRACT

The present disclosure relates to a first circuit for measuring a first current, the first circuit including a current step-down circuit, a logarithmic comparator circuit, and a differential voltage amplifier circuit. A first input of the current step-down circuit is configured to receive the first current, and a first output of the current step-down circuit is configured to provide a ratiometric step-down current to a first logarithmic amplifier via a current mirror assembly. The logarithmic comparator circuit includes the first logarithmic amplifier, configured to convert the ratiometric step-down current into a logarithmic first voltage, and a second logarithmic amplifier, configured to provide a logarithmic reference voltage. The differential voltage amplifier circuit is configured to compare the logarithmic first voltage with the logarithmic reference voltage.

### CROSS-REFERENCE TO RELATED APPLICATIONS

This application claims the priority benefit of French Patent Application No. 2400635, filed on Jan. 23, 2024, entitled “Circuit de mesure d'un courant”, which is hereby incorporated herein by reference to the maximum extent allowable by law.

### TECHNICAL FIELD

The present description relates generally to electronic circuits, devices, and methods, and more particularly to the measurement of physical quantities within an electronic circuit or device. More specifically, the present description relates to a method and circuit for measuring a current.

### BACKGROUND

In electronics, there are several techniques allowing a measurement of an electric current flowing through a conductor, an electronic component, or a circuit to be obtained.

It would be desirable to be able to improve, at least in part, some aspects of circuits for measuring a current.

### SUMMARY

There is a need for circuits for measuring a current allowing reliably measuring currents over a wide range of current.

There is a need for circuits for measuring a current allowing reliably measuring currents from 1 mA to 100 A.

One embodiment overcomes some or all of the drawbacks of known circuits for measuring a current.

One embodiment provides a circuit for measuring a current comprising at least one logarithmic amplifier.

One embodiment provides a circuit for measuring a current adapted to reliably measure a current between 1 mA and 100 A.

One embodiment provides a circuit for measuring a current between 1 mA and 100 A comprising:
a first logarithmic amplifier adapted to convert the current into a first voltage; and
a second logarithmic amplifier adapted to provide a second reference voltage.

According to one embodiment, each first, second logarithmic amplifier includes an amplifier and a bipolar transistor.

According to one embodiment, each first, second logarithmic amplifier includes an amplifier and a diode.

According to one embodiment, the circuit further comprises a resistor adapted to receive the current.

According to one embodiment, the circuit further comprises a filter circuit arranged between the resistor and the first logarithmic amplifier.

According to one embodiment, the filter circuit is an electromagnetic interference filter.

According to one embodiment, the circuit further comprises a comparator circuit adapted to receive the first voltage and the second reference voltage.

According to one embodiment, the circuit further comprises an analog-to-digital converter.

According to one embodiment, the circuit further comprises a temperature sensor.

Another embodiment provides a current measurement method using the circuit for measuring as described above.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an embodiment of a circuit for measuring a current;

FIG. 2 illustrates an example of a circuit diagram of an embodiment of a circuit for measuring a current;

FIG. 3 illustrates two curves illustrating an advantage of the embodiment shown in FIGS. 1 and 2; and

FIG. 4 illustrates an example application of the embodiment shown in FIGS. 1 and 2.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

The embodiments described below relate to current measurement, and more specifically to a circuit for measuring a current. Each circuit for measuring a current is adapted to measure a current within a certain range. The embodiments concerned here propose to expand the operating value range of a circuit for measuring a current by using at least one, preferably two, logarithmic amplifiers.

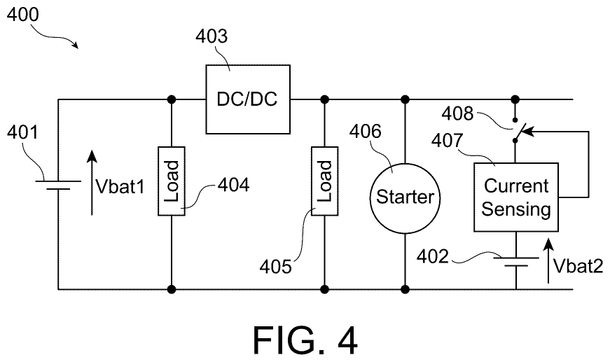

In addition, the embodiments described below are particularly suitable for any field of electronics that may use a circuit for measuring a current. A concrete example of the application of the embodiments described below is described in relation to FIG. 4.

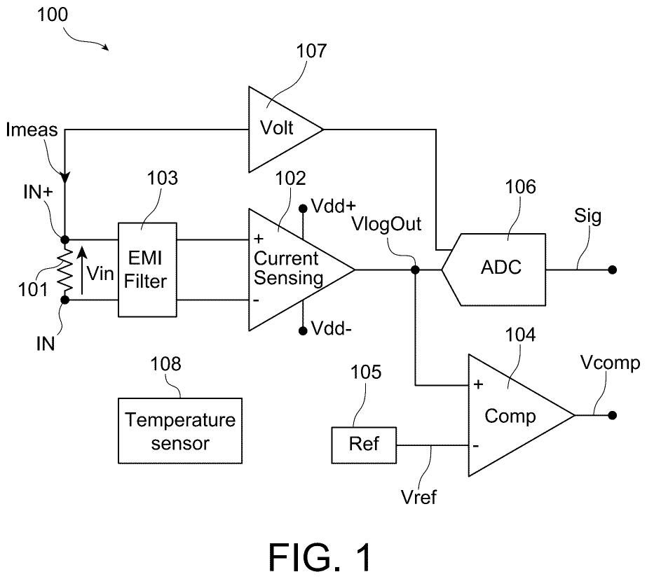

FIG. 1 illustrates, schematically and in block form, an embodiment of a circuit for measuring 100 a current Imeas.

The measuring circuit 100 comprises two input nodes IN+ and IN− adapted to receive an input voltage Vin and the current to be measured Imeas. According to one example, the input voltage Vin is a common-mode voltage. According to one example, the input voltage Vin is between −20 and 120 V, preferably between −5 and 100 V. According to one example, the current to be measured Imeas is between 1 mA and 100 A.

The measuring circuit 100 further comprises a resistor 101 coupling the two input nodes IN+ and IN−. In other words, a first terminal of resistor 101 is coupled, preferably connected, to node IN+, and a second terminal of resistor 101 is coupled, preferably connected, to node IN−. According to one example, resistor 101 is an integrated resistor or an external resistor. According to one example, resistor 101 has a resistance of between 1 and 500 mOhm.

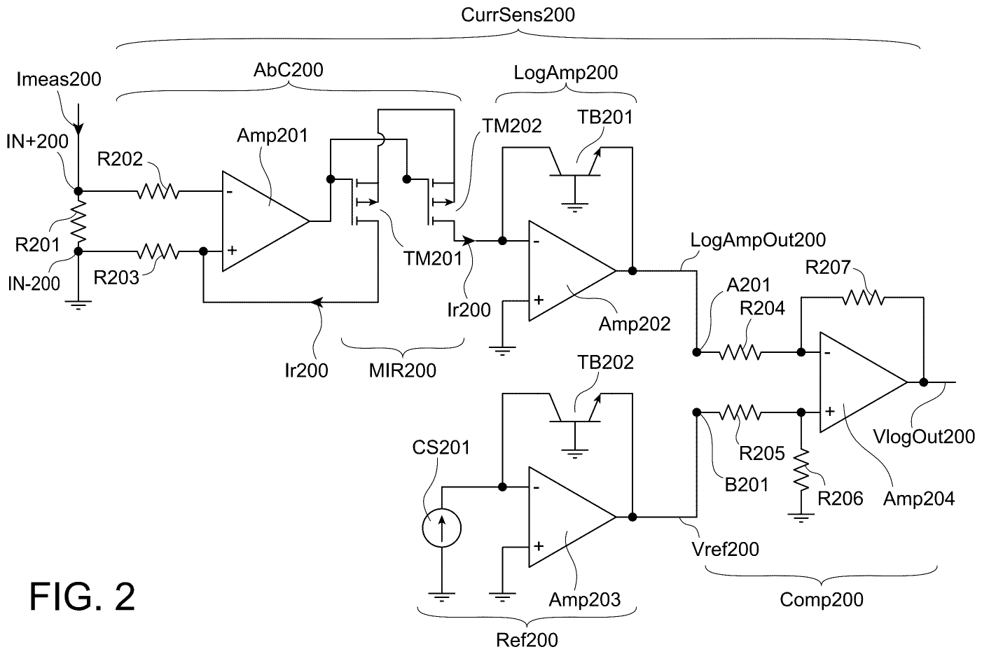

The circuit for measuring 100 further comprises a current sensing circuit 102 (Current Sensing) comprising two input terminals + and −, an output terminal, and for example two supply terminals. The input + of amplifier 102 is coupled to the input node IN+, and the input − of amplifier 102 is coupled to the input node IN−. The supply terminals receive positive Vdd+ and negative Vdd− supply voltages. The amplifier output terminal supplies an output voltage VlogOut. According to one embodiment, the current sensing circuit 102 comprises a logarithmic amplifier. A detailed example of the current sensing circuit 102 is described in relation to FIG. 2.

In this description, we call logarithmic amplifier a non-linear analog amplifier that transforms an input voltage into an output voltage according to a logarithmic function. In particular, these amplifiers allow the input signal to be compressed to have a wider operating range. A detailed example of such an amplifier will be described in relation to FIG. 2.

The measuring circuit 100 further optionally comprises a filter circuit 103 (EMI Filter) coupling the input nodes IN+ and IN− to the input terminals of the logarithmic amplifier 102. The filter circuit 103 filters out components of the input voltage Vin with frequencies that are too high. Circuit 103 comprises a first input coupled, preferably connected, to the node IN+, and a second input coupled, preferably connected, to the node IN−. In addition, circuit 103 comprises a first output coupled, preferably connected, to the input terminal + of logarithmic amplifier 102, and a second output coupled, preferably connected, to the input terminal − of logarithmic amplifier 102. According to a preferred embodiment, the filter circuit 103 is an electromagnetic interference filter, or EMI filter.

The measuring circuit 100 further optionally comprises a comparator circuit 104 (Comp), adapted to compare the output voltage VlogOut of the amplifier 102 with a reference voltage Vref. The comparator circuit 104 comprises two input terminals + and −. The input terminal + is preferably coupled to the output terminal of the logarithmic amplifier 102. The input terminal − receives, for example, a reference voltage Vref. The comparator circuit 104 outputs a voltage Vcomp.

The measuring circuit 100 further optionally comprises a reference circuit 105 (Ref) adapted to deliver the reference voltage Vref.

The measuring circuit 100 further optionally comprises an optional analog-to-digital converter circuit 106 (ADC), which receives the voltage VlogOut as an input. The circuit 106 outputs a digital signal Sig indicating the level of the current Imeas measured by the logarithmic amplifier.

The measuring circuit 100 further optionally comprises an optional voltage measuring circuit 107 (Volt) adapted to measure the level of the voltage Vin. According to one example, an output of the measuring circuit 107 is coupled, preferably connected, to an input of the analog-to-digital converter circuit 106.

The measuring circuit 100 further optionally comprises a temperature sensor 108 (Temperature sensor) adapted to monitor the temperature of the circuit 100 during operation.

The present description further relates to a method for measuring a current implementing the circuit 100.

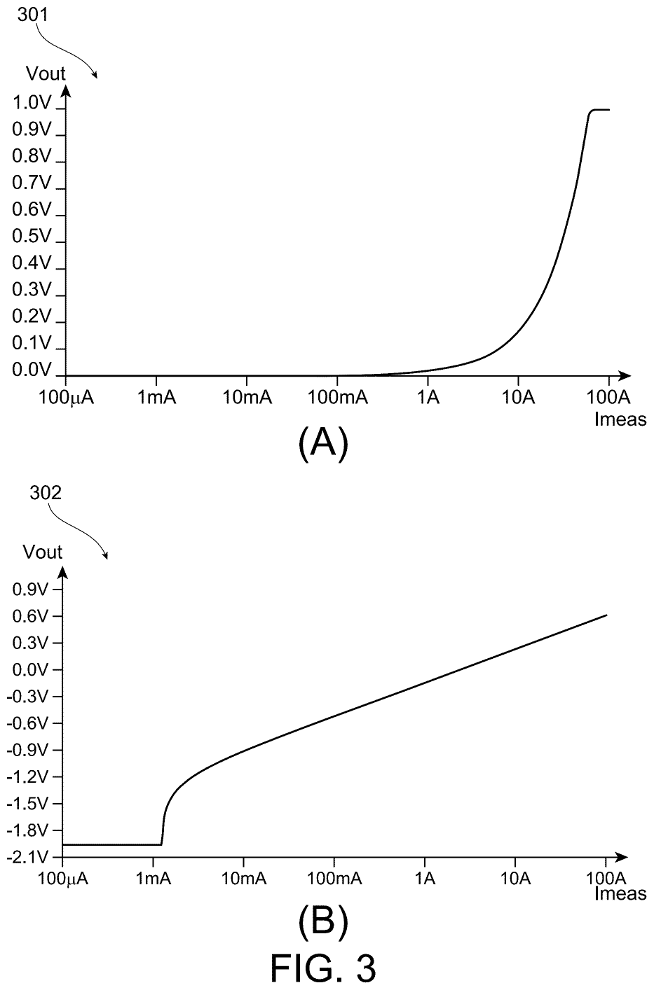

One advantage of the circuit 100 is that by using a logarithmic amplifier 102 instead of a conventional amplifier, it is possible to expand the current range measurable by the measuring circuit. This advantage is described in greater detail in relation to FIG. 3.

FIG. 2 is a schematic circuit of an embodiment of a current evaluation circuit CurrSens200 of the type of measuring circuit 102 described in relation to FIG. 1. The resistor 101 described in relation to FIG. 1 is further shown in FIG. 2 in the form of a resistor R201.

The circuit CurrSens200 is adapted to measure a current Imeas200 flowing between two input nodes IN+200 and IN−200.

The input resistor R201 is arranged between the two input nodes IN+200 and IN−200 of the circuit CurrSens200. As previously mentioned, a first terminal of resistor R201 is coupled, preferably connected, to node IN+200, and a second terminal of resistor R201 is coupled, preferably connected, to node IN−200. According to one example, resistor R201 has a resistance of 4 mOhm.

According to one embodiment, the circuit CurrSens200 comprises:
a current step-down circuit AbC200;
a logarithmic comparator LogAmp200;
a reference circuit Ref200; and
a comparison circuit Comp200.

According to one example, the current step-down circuit AbC200 comprises an amplifier Amp201, two resistors R202 and R203, and a current mirror assembly MIR200.

Resistor R202 couples the inverting input of amplifier Amp201 to node IN+200, and resistor R203 couples the non-inverting input of amplifier Amp201 to node IN−200. In other words, a first terminal of resistor R202 is coupled, preferably connected, to node IN+200, and a second terminal of resistor R202 is coupled, preferably connected, to the inverting input of amplifier Amp201. Similarly, a first terminal of resistor R203 is coupled, preferably connected, to node IN−200, and a second terminal of resistor R203 is coupled, preferably connected, to the non-inverting input of amplifier Amp201. The amplifier Amp201 further receives two supply voltages (not shown in FIG. 2).

The current mirror assembly MIR200 includes two transistors TM201 and TM202. According to one example, transistors TM201 and TM202 are metal-oxide gate field-effect transistors, or insulated gate field-effect transistors, or MOSFET (metal-oxide-semiconductor field-effect transistor) transistors, or MOS transistors. More specifically, transistors TM201 and TM202 are, in FIG. 2, P-channel MOS transistors, or PMOS transistors. Transistors TM201 and TM202 have their source terminals coupled, preferably connected, to each other. Transistors TM201 and TM202 have their gate terminals coupled, preferably connected, to each other, and to the output terminal of amplifier Amp201. The drain terminal of transistor TM201 is coupled, preferably connected, to the non-inverting input of amplifier Amp201. The drain terminal of transistor TM202 supplies a current Ir200 which is the image of the current at the non-inverting input terminal of amplifier Amp201.

In particular, the current Ir200 is given by the following mathematical formula:

$$Ir 200 = Imeas 200 * \frac{R 201}{R 203} , \qquad [ Math 1 ]$$

wherein:
   R201 represents the value of resistor R201; and
   R203 represents the value of resistor R203.

According to a first example shown in FIG. 2, the logarithmic amplifier LogAmp200 consists of an amplifier Amp202 and a bipolar transistor TB201 connected “in parallel” with the amplifier Amp202. According to one example, the bipolar transistor TB201 is an NPN transistor. The inverting input of amplifier Amp202 is adapted to receive current Ir200. According to one example, the inverting input of the amplifier Amp202 is coupled, preferably connected, directly to the drain terminal of the transistor TM202 of the circuit ABC200. The non-inverting input of amplifier Amp202 receives a ground voltage. The amplifier Amp202 outputs an output voltage LogAmpOut200 of the logarithmic amplifier LogAmp200. The amplifier Amp202 further receives two supply voltages (not shown in FIG. 2). A collector terminal of transistor TB201 is coupled, preferably connected, to the inverting input of amplifier Amp202, and an emitter terminal of transistor TB201 is coupled, preferably connected, to the output of amplifier Amp202. The base terminal of transistor TB201 receives a control voltage enabling it to be in a saturation mode.

The output voltage VlogOut200 is given by the following mathematical formula:

$$LogAmpOut 200 = V t * ln ( \frac{Ir 200}{Is 201} ) , \qquad [ Math 2 ]$$

wherein:
   Vt represents the thermal voltage of transistor TB201; and
   Is201 is the saturation current of transistor TB201.

According to a second example not shown in FIG. 2, the logarithmic amplifier LogAmp200 consists of the amplifier Amp202 and a diode replacing the bipolar transistor TB201. According to one example, the anode of the diode is coupled, preferably connected, to the inverting input of the amplifier Amp202, and the cathode of the diode is coupled, preferably connected, to the output of the amplifier Amp202.

According to one example, the comparison circuit Comp200 comprises an input node A201 receiving the voltage VlogOut200, and an input node B201 receiving a reference voltage Vref200.

According to one example, the comparison circuit Comp200 further comprises an amplifier Amp204 and two resistors R204 and R205. Resistor R204 couples the inverting input of amplifier Amp201 to node A201, and resistor R205 couples the non-inverting input of amplifier Amp204 to node B210. In other words, a first terminal of resistor R204 is coupled, preferably connected, to node A201, and a second terminal of resistor R204 is coupled, preferably connected, to the inverting input of amplifier Amp204. Similarly, a first terminal of resistor R205 is coupled, preferably connected, to node B201, and a second terminal of resistor R205 is coupled, preferably connected, to the non-inverting input of amplifier Amp204. The amplifier Amp204 further receives two supply voltages (not shown in FIG. 2). The output of amplifier Amp204 provides a voltage Vcomp200. According to one example, resistors R204 and R205 have equal resistances to each other, and, for example, equal to 200 Ohm.

The comparator circuit Comp200 further comprises resistors R206 and R207. Resistor R206 couples the non-inverting input of amplifier Amp204 to ground. In other words, a first terminal of resistor R206 is coupled, preferably connected, to the non-inverting input of amplifier Amp204, and a second terminal of resistor R206 receives the ground voltage. Resistor R207 couples the output of amplifier Amp204 to its inverting input. In other words, a first terminal of resistor R207 is coupled, preferably connected, to the output of amplifier Amp204, and a second terminal of resistor R207 is coupled, preferably connected, to the inverting input of amplifier Amp204. According to one example, resistors R206 and R207 have resistances equal to each other, and, for example, equal to 1 250 Ohm.

According to one example, the reference circuit Ref200 consists of a logarithmic amplifier identical to the logarithmic amplifier LogAmp200 and a current source CS201.

According to a first example shown in FIG. 2, the logarithmic amplifier of the circuit Ref200 consists of an amplifier Amp203 and a bipolar transistor TB202 connected “in parallel” with the amplifier Amp203. According to one example, the bipolar transistor TB202 is an NPN transistor. The inverting input of amplifier Amp203 is adapted to receive the current supplied by current source CS201. According to one embodiment, the current source CS201 is calibrated to provide a known reference current value. This calibration may take place during manufacture of the circuit CurrSens200, or may be calibrated during use of the circuit CurrSens200. The non-inverting input of the amplifier Amp203 receives the ground voltage. The amplifier Amp203 outputs the reference voltage Vref200 of the circuit Ref200. The amplifier Amp203 further receives two supply voltages (not shown in FIG. 2). A collector terminal of transistor TB202 is coupled, preferably connected, to the inverting input of amplifier Amp203, and an emitter terminal of transistor TB202 is coupled, preferably connected, to the output of amplifier Amp203. The base terminal of transistor TB202 receives a control voltage enabling it to be in a saturation mode.

The reference voltage Vref200 is given by the following mathematical formula:

$$Vref 200 = Vt * ln ( \frac{Ics 201}{Is 202} ) . \qquad [ Math 3 ]$$

According to the second example not shown in FIG. 2, the logarithmic amplifier of the circuit Ref200 consists of the amplifier Amp203 and a diode replacing the bipolar transistor TB202. In this case, the logarithmic amplifier of the circuit Ref200 further comprises a diode in place of the bipolar transistor TB202. According to one example, the anode of the diode is coupled, preferably connected, to the inverting input of the amplifier Amp203, and the cathode of the diode is coupled, preferably connected, to the output of the amplifier Amp203.

Thus, the comparison voltage VlogOut200 of the comparison circuit Comp200 is given by the following mathematical formula:

$$Vcomp 200 = Vt * ln ( \frac{Imeas 200 * R 201}{Ics 201 * R 203} ) * \frac{R 207}{R 204} , \qquad [ Math 1 ]$$

wherein:
Vt represents the thermal voltage of transistor TB201;
Imeas200 is the current flowing through resistor R201; and
IcS201 is the current supplied by current source CS201.

FIG. 3 shows two curves (A) and (B) illustrating the performance of a circuit for measuring a current.

In particular, curve (A) illustrates the output voltage (Vout) of a circuit for measuring a current comprising a conventional amplifier, not a logarithmic amplifier, as a function of the current to be measured (Imeas).

Curve (B) illustrates the output voltage (Vout) of a circuit for measuring a current comprising a logarithmic amplifier, of the type of circuit 102 shown in FIG. 1, as a function of the current to be measured (Imeas).

It clearly appears that the circuit in curve (A) has an operating zone for a current to be measured of between 100 mA and 60 A. This is not the case for the circuit in curve (B), the evolution pf which increases for a current to be measured of between 1 mA and 100 A.

FIG. 4 illustrates, schematically and in block form, an example application of a measuring circuit of the type of the circuits 100 described in relation to FIG. 1. More precisely, FIG. 4 illustrates a circuit 400 comprising several supply means.

Circuit 400 comprises a first power supply source 401, e.g. a battery, providing a first voltage Vbat1, and a second power supply source 402, e.g. a battery, providing a second voltage Vbat2, and a converter 403 (DC/DC) converting a direct voltage to a direct voltage, or DC-DC converter. According to one example, the DC-DC converter 403 is adapted to convert the voltage Vbat1 into the voltage Vbat2, and vice versa.

According to one example, circuit 400 uses power supply sources 401 and 402 to supply loads 404 (load) and 405 (load).

According to one embodiment, load 404 is connected in parallel with power supply source 401, and load 405 is connected in parallel with power supply source 402.

According to one example, the circuit 400 may further comprise one or more starter circuits 406 (Starter) arranged in parallel with one of the power supply sources 401 and/or 402. In the case illustrated in FIG. 4, circuit 400 comprises a starter circuit 400 coupled in parallel with load 405.

According to one embodiment, circuit 400 comprises one or more circuits for measuring a current 407 of the type of the circuits for measuring a current Imeas200 shown in FIG. 1. Such circuits can be used to activate or deactivate power supply sources. In the case shown in FIG. 4, circuit 400 comprises a circuit for measuring a current 407 adapted to drive a switch 408 enabling or disabling power supply source 402.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

What is claimed is:

1. A first circuit for measuring a first current, the first circuit comprising:
a current step-down circuit comprising:
a current feedback amplifier configured to receive the first current and provide a ratiometric step-down current; and
a current mirror assembly configured to transfer the ratiometric step-down current to a first logarithmic amplifier;
a logarithmic comparator circuit comprising:
the first logarithmic amplifier, configured to receive the transferred ratiometric step-down current and provide a logarithmic measurement voltage output;
a second logarithmic amplifier configured to receive a reference current input and provide a logarithmic reference voltage output; and
a differential voltage amplifier circuit comprising a second amplifier including:
an inverting input coupled to the logarithmic measurement voltage output of the logarithmic comparator circuit;
a noninverting input coupled to the logarithmic reference voltage output of the logarithmic comparator circuit; and
an amplified comparison voltage output configured to indicate a level of the first current.

2. The first circuit according to claim 1, further comprising a first resistor having a first terminal configured to receive the first current, and a second terminal coupled to a ground.

3. The first circuit according to claim 2, wherein:
the current feedback amplifier has an inverting input coupled to first terminal of the first resistor, a noninverting input coupled to the second terminal of the first resistor, and an amplifier output coupled to the current mirror assembly; and
the current mirror assembly has a current mirror input coupled to the current feedback amplifier.

4. The first circuit according to claim 3, further comprising:
a second resistor disposed between the first terminal of the first resistor and the inverting input of the current feedback amplifier; and
a third resistor disposed between the second terminal of the first resistor and the noninverting input of the current feedback amplifier.

5. The first circuit according to claim 3, wherein the current mirror assembly comprises first and second transistors having source terminals coupled to each other, gate terminals coupled to each other and to the amplifier output of the current feedback amplifier, wherein a drain terminal of the first transistor is coupled to the noninverting input of the current feedback amplifier, and wherein a drain terminal of the second transistor provides the ratiometric step-down current.

6. The first circuit according to claim 1, wherein:
the first logarithmic amplifier is configured to receive the transferred ratiometric step-down current at an inverting input; and
the second logarithmic amplifier is configured to receive the reference current input at an inverting input.

7. The first circuit according to claim 6, wherein:
the first logarithmic amplifier has a noninverting input coupled to a ground; and
the second logarithmic amplifier has a noninverting input coupled to the ground.

8. The first circuit according to claim 7, wherein:
the first logarithmic amplifier includes a first diode or a first bipolar transistor having conduction terminals coupled between the inverting input and the logarithmic measurement voltage output of the first logarithmic amplifier; and
the second logarithmic amplifier includes a second diode or a second bipolar transistor having conduction terminals coupled between the inverting input and the logarithmic reference voltage output of the second logarithmic amplifier.

9. The first circuit according to claim 7, wherein the first circuit further comprises a current source providing a reference current to the second logarithmic amplifier.

10. The first circuit according to claim 1, wherein the differential voltage amplifier circuit further comprises:
a fourth resistor disposed between the logarithmic measurement voltage output of the logarithmic comparator circuit and the noninverting input of the second amplifier; and
a fifth resistor disposed between the logarithmic reference voltage output of the logarithmic comparator circuit and the noninverting input of the second amplifier.

11. The first circuit according to claim 10, wherein the differential voltage amplifier circuit further comprises a sixth resistor disposed between the amplified comparison voltage output of the second amplifier and the noninverting input of the second amplifier.

12. The first circuit according to claim 1, further comprising an analog-to-digital converter having an analog input coupled to the amplified comparison voltage output of the differential voltage amplifier circuit, and a digital output configured to indicate a digital level of the first current.

13. The first circuit according to claim 1, further comprising a temperature sensor configured to monitor a temperature of the first circuit during operation.

14. The first circuit according to claim 1, wherein the first circuit is configured to measure the first current anywhere between 1 mA and 100 A.

15. A first circuit for measuring a first current, the first circuit comprising:
a current step-down circuit, wherein a first input of the current step-down circuit is configured to receive the first current, and a first output of the current step-down circuit is configured to provide a ratiometric step-down current to a first logarithmic amplifier via a current mirror assembly;
a logarithmic comparator circuit comprising:
the first logarithmic amplifier, configured to convert the ratiometric step-down current into a logarithmic first voltage; and
a second logarithmic amplifier, configured to provide a logarithmic reference voltage; and
a differential voltage amplifier circuit configured to compare the logarithmic first voltage with the logarithmic reference voltage.

16. The first circuit according to claim 15, further comprising a first resistor having a first terminal configured to receive the first current, and a second terminal coupled to a ground, and wherein the current step-down circuit comprises:
a current feedback amplifier having an inverting input coupled to first terminal of the first resistor, a noninverting input coupled to the second terminal of the first resistor, and an amplifier output coupled to the current mirror assembly; and
the current mirror assembly, having a current mirror input coupled to the current feedback amplifier, and an output providing the ratiometric step-down current.

17. The first circuit according to claim 15, wherein:
the first logarithmic amplifier includes a third amplifier, and a first bipolar transistor or a first diode; and
the second logarithmic amplifier includes a fourth amplifier, and a second bipolar transistor or a second diode.

18. A method for measuring a first current by a first circuit, the method comprising:
receiving, by a current step-down circuit, the first current;
generating, by the current step-down circuit, a ratiometric step-down current;
converting, by a first logarithmic amplifier, the ratiometric step-down current into a first voltage;
providing, by a second logarithmic amplifier, a reference voltage;
comparing, by a differential voltage amplifier circuit, the first voltage with the reference voltage; and
generating, by the differential voltage amplifier circuit, an amplified comparison voltage indicating a level of the first current.

19. The method according to claim 18, further comprising:
providing a ground reference to each of the first and second logarithmic amplifiers; and
providing, by a current source, a calibrated current to the second logarithmic amplifier.

20. The method according to claim 18, further comprising converting, by an analog-to-digital converter, the amplified comparison voltage into a digital signal indicating the level of the first current.
